(19) United States
(12) Patent Application Publication
(10) Pub. No.: US 2026/0097952 A1
(43) Pub. Date: Apr. 9, 2026

(54) MEMS Sensor Module

(71) Applicant: AAC ACOUSTIC TECHNOLOGIES (SHENZHEN) CO., LTD., Shenzhen (CN)

(72) Inventors: Zhongzong Gan, Shenzhen (CN); Rui Cai, Shenzhen (CN); Yaqi Wang, Shenzhen (CN); Rui Zhang, Shenzhen (CN)

(21) Appl. No.: 19/001,368

(22) Filed: Dec. 24, 2024

Related U.S. Application Data
(63) Continuation of application No. PCT/CN2024/123569, filed on Oct. 9, 2024.

(51) Int. Cl. B81B 7/00

(52) U.S. Cl. CPC B81B 7/0019; B81B 2201/0257; B81B 2207/015; B81B 2207/07

(57) ABSTRACT

A MEMS sensor module includes an inner space enclosed by a side wall, a dividing wall for dividing the inner space into two cavities, a first circuit board, a second circuit board, two MEMS sensors respectively disposed in the two cavities, and two golden finger layers. One or both of the two golden finger layers at the dividing wall have a notch communicating the two cavities. One MEMS sensor includes an ASIC chip on the second circuit board and a MEMS chip on the ASIC chip. Another MEMS sensor includes an ASIC chip on the first circuit board and a MEMS chip on the second circuit board. The side wall has a conductor connecting the two circuit boards. A bonding wire connects the MEMS chip and the second circuit board. The MEMS sensor module can avoid the heat generated by one MEMS sensor affecting another one.

### FIELD OF THE PRESENT DISCLOSURE

The present disclosure relates to sensors, in particular to a MEMS sensor module.

### DESCRIPTION OF THE RELATED ART

A MEMS sensor module in the related art has a plurality of built-in MEMS sensors to achieve at least one sensor function, such as a pressure sensor, a microphone sensor, a gas sensor, etc.

Each MEMS sensor has a MEMS chip and an ASIC chip. However, some ASIC chips generate a large amount of heat when working, the heat diffuses through a circuit board or thermal motion of air in the module and affects some temperature-sensitive MEMS sensors. As a result, these affected MEMS sensors have weakened working performances, and they cannot work normally.

Thus, it is necessary to provide a novel MEMS sensor module to solve the problems.

### SUMMARY

An objective of the present disclosure is to overcome the above problems and provide a MEMS sensor module which can avoid the heat generated by the ASIC chip of one of the MEMS sensors therein affecting another one.

In order to achieve the objective mentioned above, the present disclosure discloses a MEMS sensor module including an inner space enclosed by a side wall, a first circuit board disposed on a top of the side wall, a second circuit board disposed on a bottom of the side wall, a dividing wall disposed in the inner space and connected to the side wall for dividing the inner space into a first cavity and a second cavity, a first MEMS sensor disposed in the first cavity and including a first ASIC chip mounted on the second circuit board and a first MEMS chip stacked on the first ASIC chip, a second MEMS sensor disposed in the second cavity and including a second ASIC chip mounted on the first circuit board and a second MEMS chip mounted on the second circuit board, a first golden finger layer disposed between the side wall and the first circuit board as well as between the dividing wall and the first circuit board for respectively surrounding the first cavity and the second cavity, and a second golden finger layer disposed between the side wall and the second circuit board as well as between the dividing wall and the second circuit board for respectively surrounding the first cavity and the second cavity. A first bonding wire connects the first MEMS chip and the second circuit board. A second bonding wire connects the second MEMS chip and the second circuit board. The side wall is provided with a conductor connecting the first circuit board and the second circuit board. A notch communicating the first cavity and the second cavity is provided in the first golden finger layer at the dividing wall and/or the second golden finger layer at the dividing wall.

As an improvement, a total area of the notch is less than 6400 μm².

As an improvement, the first bonding wire is arranged at a position except between the first MEMS chip and the dividing wall. The second bonding wire is arranged at a position except between the second MEMS chip and the dividing wall.

As an improvement, the dividing wall is provided with a through hole communicating the first cavity and the second cavity. A total area of the through hole is less than 6400 μm².

As an improvement, an inner surface of the side wall enclosing the inner space is a metallized surface.

As an improvement, each of the first circuit board and the second circuit board is embedded with a capacitor and a resistor that are used for eliminating high frequency signal interference.

As an improvement, the second circuit board is provided with a penetrating hole at a position corresponding to the second MEMS chip. The penetrating hole communicates the second MEMS chip and the outside of the MEMS sensor module.

In the MEMS sensor module according to the present disclosure, the first golden finger layer respectively surrounds the first cavity and the second cavity, and the second golden finger layer respectively surrounds the first cavity and the second cavity, thereby separating the respective regions of the first cavity and the second cavity. Besides, the first ASIC chip is mounted on the second circuit board, and the second ASIC chip is mounted on the first circuit board, thereby increasing the spatial distance between the first ASIC chip and the second ASIC chip. Thus, the MEMS sensor module can avoid the heat generated by the ASIC chip of one of the MEMS sensors therein affecting another one.

### BRIEF DESCRIPTION OF THE DRAWINGS

In order to more clearly illustrate the technical solutions in embodiments of the present disclosure, the accompanying drawings used in the description of the embodiments will be briefly introduced below. It is apparent that, the accompanying drawings in the following description are only some embodiments of the present disclosure, and other drawings can be obtained by those of ordinary skill in the art based on the accompanying drawings without creative efforts, wherein:

FIG. 1 is an isometric view of a MEMS sensor module of the present disclosure.

FIG. 2 is an exploded view of the MEMS sensor module of the present disclosure.

FIG. 3 is an exploded view of the MEMS sensor module of the present disclosure, from another aspect.

FIG. 4 is a cross-sectional view of the MEMS sensor module of the present disclosure.

### DETAILED DESCRIPTION OF THE EMBODIMENTS

The technical solutions in embodiments of the present disclosure will be described clearly and completely below with reference to the accompanying drawings in the embodiments of the present disclosure. It is apparent that, the described embodiments are merely some of rather than all of the embodiments of the present disclosure. All other embodiments acquired by those of ordinary skill in the art without creative efforts based on the embodiments of the present disclosure shall fall within the protection scope of the present disclosure.

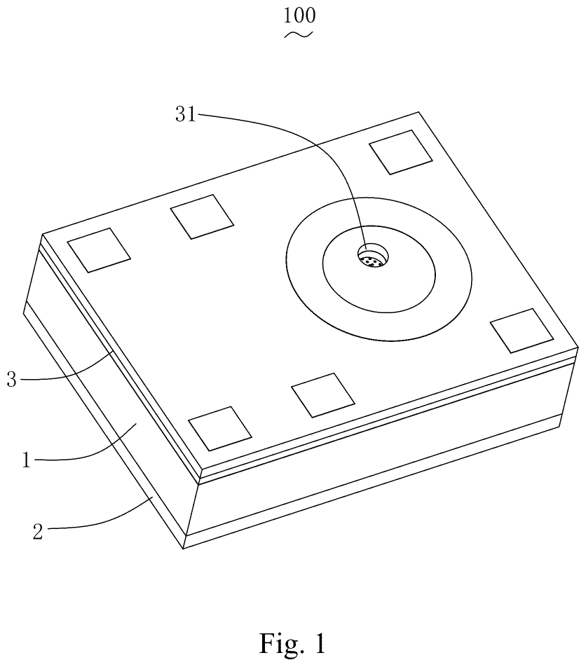

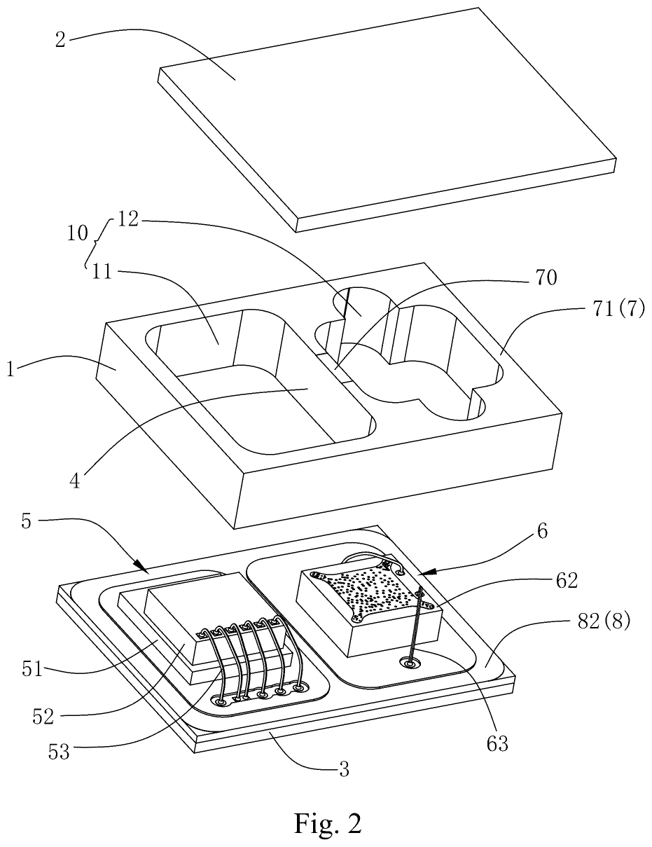

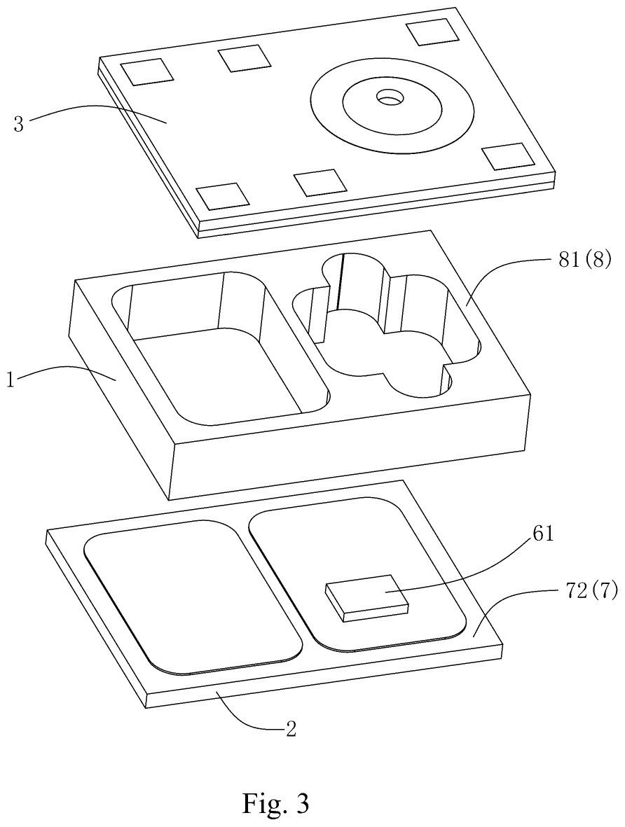

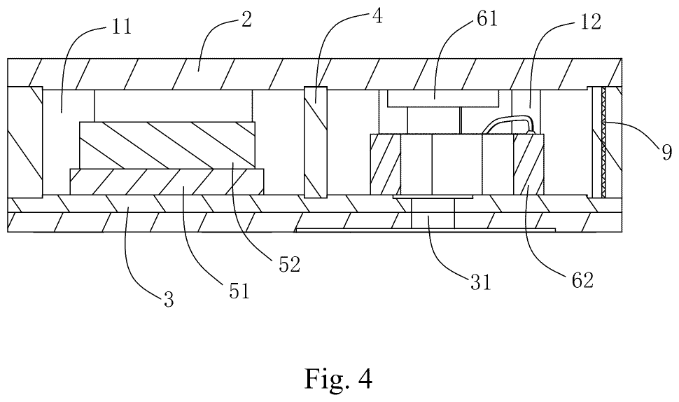

Referring to FIGS. 1-4, the present disclosure discloses a MEMS sensor module 100 including an inner space 10 enclosed by a side wall 1, a first circuit board 2 disposed on a top of the side wall 1, a second circuit board 3 disposed on a bottom of the side wall 1, a dividing wall 4 disposed in the inner space 10 and connected to the side wall 1, and a first MEMS sensor 5 and a second MEMS sensor 6 that are disposed in the inner space 10. The first MEMS sensor 5 and the second MEMS sensor 6 can achieve at least one sensor function, such as a pressure sensor, a microphone sensor, a gas sensor, etc.

The dividing wall 4 divides the inner space 10 into a first cavity 11 and a second cavity 12. The first MEMS sensor 5 is disposed in the first cavity 11, and the second MEMS sensor 6 is disposed in the second cavity 12. A first golden finger layer 7 is disposed between the side wall 1 and the first circuit board 2 as well as between the dividing wall 4 and the first circuit board 2. The first golden finger layer 7 respectively surrounds the first cavity 11 and the second cavity 12. A second golden finger layer 8 is disposed between the side wall 1 and the second circuit board 3 as well as between the dividing wall 4 and the second circuit board 3. The second golden finger layer 8 respectively surrounds the first cavity 11 and the second cavity 12. The first golden finger layer 7 and the second golden finger layer 8 separate the respective regions of the first cavity 11 and the second cavity 12, thus, the first MEMS sensor 5 and the second MEMS sensor 6 have their own regions.

Optionally, the first golden finger layer 7 can include a first part 71 disposed on the side wall 1 and the dividing wall 4, and a second part 72 disposed on the first circuit board 2. A projection of the first part 71 coincides with a projection of the second part 72. The first part 71 and the second part 72 combine to form the first golden finger layer 7. Furthermore, the first golden finger layer 7 can also be formed in other ways, not limited to the combination of two parts.

Similarly, the second golden finger layer 8 can include a first part 81 disposed on the side wall 1 and the dividing wall 4, and a second part 82 disposed on the second circuit board 3. A projection of the first part 81 coincides with a projection of the second part 82. The first part 81 and the second part 82 combine to form the second golden finger layer 8. Furthermore, the second golden finger layer 8 can also be formed in other ways, not limited to the combination of two parts.

In this embodiment, a notch 70 communicating the first cavity 11 and the second cavity 12 is provided in the first golden finger layer 7 at the dividing wall 4. The notch 70 can realize the need for air permeability of the MEMS sensor module 100, so as to reduce the need for air holes in the side wall 1, the first circuit board 2 and the second circuit board 3 of the MEMS sensor module 100, thus facilitating the back-end application design and saving the back-end application cost. It is noted that the notch 70 may be provided in the first part 71 and/or the second part 72 of the first golden finger layer 7 in the situation of the combination of two parts forming the first golden finger layer 7.

In some embodiments, the notch 70 can also be provided in the second golden finger layer 8 at the dividing wall 4. Similarly, the notch 70 may be provided in the first part 81 and/or the second part 82 of the second golden finger layer 8 in the situation of the combination of two parts forming the second golden finger layer 8. In some embodiments, the notch 70 can also be provided both in the first golden finger layer 7 at the dividing wall 4 and the second golden finger layer 8 at the dividing wall 4. In different embodiments of the notch 70, a total area of the notch 70 is less than 6400 μm².

In some embodiments, the dividing wall 4 may be provided with a through hole communicating the first cavity 11 and the second cavity 12, and a total area of the through hole is less than 6400 μm².

The first MEMS sensor 5 includes a first ASIC chip 51 mounted on the second circuit board 3 and a first MEMS chip 52 stacked on the first ASIC chip 51. A first bonding wire 53 connects the first MEMS chip 52 and the second circuit board 3. The first ASIC chip 51 can be mounted on the second circuit board 3 through surface mount technology. The first ASIC chip 51 is electrically conductive with the second circuit board 3.

The second MEMS sensor 6 includes a second ASIC chip 61 mounted on the first circuit board 2 and a second MEMS chip 62 mounted on the second circuit board 3. The second ASIC chip 61 can be mounted on the first circuit board 2 through surface mount technology. The second ASIC chip 61 is electrically conductive with the first circuit board 2. The side wall 1 is provided with a conductor 9 connecting the first circuit board 2 and the second circuit board 3 to electrically conduct the second ASIC chip 61 with the second circuit board 3. A second bonding wire 63 connects the second MEMS chip 62 and the second circuit board 3.

The first ASIC chip 51 is mounted on the second circuit board 3, and the second ASIC chip 61 is mounted on the first circuit board 2, thereby increasing the spatial distance between the first ASIC chip 51 and the second ASIC chip 61 to reduce mutual interference with each other.

In this embodiment, the second circuit board 3 is provided with a penetrating hole 31 at a position corresponding to the second MEMS chip 62. The penetrating hole 31 communicates the second MEMS chip 62 and the outside of the MEMS sensor module 100. Optionally, the penetrating hole 31 may be a sound inlet, and the second MEMS chip 62 may be a MEMS microphone chip.

The first bonding wire 53 is arranged at a position except between the first MEMS chip 52 and the dividing wall 4, and the second bonding wire 63 is arranged at a position except between the second MEMS chip 62 and the dividing wall 4, thereby increasing the spatial distance between the first bonding wire 53 and the second bonding wire 63 to reduce mutual interference with each other.

Optionally, an inner surface of the side wall 1 enclosing the inner space 10 is a metallized surface, so as to satisfy the need for resisting RF interference of the MEMS sensor module 100.

Optionally, each of the first circuit board 2 and the second circuit board 3 is embedded with a capacitor and a resistor that are used for eliminating high frequency signal interference.

In the MEMS sensor module 100 according to the present disclosure, the first golden finger layer 7 respectively surrounds the first cavity 11 and the second cavity 12, and the second golden finger layer 8 respectively surrounds the first cavity 11 and the second cavity 12, thereby separating the respective regions of the first cavity 11 and the second cavity 12. Besides, the first ASIC chip 51 is mounted on the second circuit board 3, and the second ASIC chip 61 is mounted on the first circuit board 2, thereby increasing the spatial distance between the first ASIC chip 51 and the second ASIC chip 61. Thus, the MEMS sensor module 100 can avoid the heat generated by the ASIC chip of one of the MEMS sensors therein affecting another one.

The above are only embodiments of the present disclosure. It should be pointed out that those of ordinary skill in the art may also make improvements without departing from the ideas of the present disclosure, all of which fall within the protection scope of the present disclosure.

What is claimed is:

1. A MEMS sensor module, comprising:
an inner space enclosed by a side wall;
a first circuit board disposed on a top of the side wall;
a second circuit board disposed on a bottom of the side wall;
a dividing wall disposed in the inner space and connected to the side wall for dividing the inner space into a first cavity and a second cavity;
a first MEMS sensor disposed in the first cavity, comprising a first ASIC chip mounted on the second circuit board and a first MEMS chip stacked on the first ASIC chip;
a second MEMS sensor disposed in the second cavity, comprising a second ASIC chip mounted on the first circuit board and a second MEMS chip mounted on the second circuit board;
a first golden finger layer disposed between the side wall and the first circuit board as well as between the dividing wall and the first circuit board for respectively surrounding the first cavity and the second cavity; and
a second golden finger layer disposed between the side wall and the second circuit board as well as between the dividing wall and the second circuit board for respectively surrounding the first cavity and the second cavity,
wherein, a first bonding wire connects the first MEMS chip and the second circuit board, a second bonding wire connects the second MEMS chip and the second circuit board, the side wall is provided with a conductor connecting the first circuit board and the second circuit board, a notch communicating the first cavity and the second cavity is provided in the first golden finger layer at the dividing wall and/or the second golden finger layer at the dividing wall.

2. The MEMS sensor module as described in claim 1, wherein a total area of the notch is less than 6400 μm².

3. The MEMS sensor module as described in claim 1, wherein the first bonding wire is arranged at a position except between the first MEMS chip and the dividing wall, the second bonding wire is arranged at a position except between the second MEMS chip and the dividing wall.

4. The MEMS sensor module as described in claim 1, wherein the dividing wall is provided with a through hole communicating the first cavity and the second cavity, a total area of the through hole is less than 6400 μm².

5. The MEMS sensor module as described in claim 1, wherein an inner surface of the side wall enclosing the inner space is a metallized surface.

6. The MEMS sensor module as described in claim 1, wherein each of the first circuit board and the second circuit board is embedded with a capacitor and a resistor that are used for eliminating high frequency signal interference.

7. The MEMS sensor module as described in claim 1, wherein the second circuit board is provided with a penetrating hole at a position corresponding to the second MEMS chip, the penetrating hole communicates the second MEMS chip and the outside of the MEMS sensor module.
